(19) United States
(12) Patent Application Publication
(10) Pub. No.: US 2026/0107820 A1
(43) Pub. Date: Apr. 16, 2026

(54) MANUFACTURE METHOD FOR A PACKAGING SUBSTRATE

(71) Applicant: Absolics Inc., Covington, GA (US)

(72) Inventors: SI HUN LEE, Covington, GA (US); Tae Kyoung KIM, Covington, GA (US)

(73) Assignee: Absolics Inc., Covington, GA (US)

(21) Appl. No.: 19/358,439

(22) Filed: Oct. 15, 2025

Related U.S. Application Data
(60) Provisional application No. 63/707,741, filed on Oct. 15, 2024.

(51) Int. Cl. H01L 21/56; H01L 21/48; H01L 23/13; H01L 23/15; H01L 23/29

(52) U.S. Cl. CPC H10W 74/01; H10W 99/00; H10W 70/68; H10W 70/692; H10W 74/473

(57) ABSTRACT

A method of manufacturing a packaging substrate according to the present disclosure comprises a preparation step of preparing a preliminary substrate including a glass core on which a device portion including a device is mounted; and an encapsulation layer forming step of manufacturing the packaging substrate by forming an encapsulation layer surrounding at least a portion of the device portion with an encapsulation layer-forming composition. The glass core comprises a cavity portion that is a space formed by being recessed on an upper surface side of the glass core. The device portion is disposed in the cavity portion. A viscosity of the encapsulation layer-forming composition at 25° C. is 12,000 cps to 38,000 cps.

In this case, it is possible to suppress occurrence of voids in the encapsulation layer, and it is possible to suppress occurrence of defects such as the glass core and the encapsulation layer which may occur in the manufacturing process.

### CROSS-REFERENCE TO RELATED APPLICATION

This application claims the benefit under 35 USC § 119 (e) of U.S. Provisional Patent Application No. 63/707,741, filed on Oct. 15, 2024, the entire disclosure of which is incorporated herein by reference for all purposes.

### BACKGROUND

### 1. Field

The present disclosure relates to a method of manufacturing a packaging substrate.

### 2. Discussion of Related Art

In manufacturing electronic components, implementing a circuit on a semiconductor wafer is called a front-end process (FE: Front-End), and assembling the wafer into a state usable in actual products is called a back-end process (BE: Back-End). The packaging process is included in the back-end process.

Among the four core technologies of the semiconductor industry that have enabled the rapid development of electronic products in recent years are semiconductor technology, semiconductor packaging technology, manufacturing process technology, and software technology. Semiconductor technology has developed in various forms, such as line widths at the nano scale below microns, over tens of millions of cells, high-speed operation, and large heat dissipation. However, the technology for perfectly packaging such semiconductors has relatively not kept pace. Accordingly, the electrical performance of the semiconductor may be determined not by the performance of the semiconductor technology itself but by the packaging technology and the resulting electrical connection.

As materials for packaging substrates, ceramics or resins are applied. In the case of a ceramic substrate, it has a high resistance value or high dielectric constant, making it difficult to mount high-performance, high-frequency semiconductor devices. In the case of a resin substrate, high-performance, high-frequency semiconductor devices may relatively be mounted, but there is a limitation in reducing the pitch of wiring.

Recently, research is underway applying silicon or glass as high-end packaging substrates. Through-holes are formed in a silicon or glass substrate, and a conductive material is applied to these through-holes, thereby shortening the wiring length between the device and the motherboard and achieving excellent electrical characteristics.

### SUMMARY

A method of manufacturing a packaging substrate according to one embodiment of the present specification comprises:
a preparation step of preparing a preliminary substrate including a glass core on which a device portion including a device is mounted; and
an encapsulation layer forming step of manufacturing the packaging substrate by forming an encapsulation layer surrounding at least a portion of the device portion with an encapsulation layer-forming composition.

The glass core comprises a cavity portion that is a space formed by being recessed on an upper surface side of the glass core.

The device portion is disposed in the cavity portion.

A viscosity of the encapsulation layer-forming composition at 25° C. is 12,000 cps to 38,000 cps.

The cavity portion may comprise a cavity opening disposed on the upper surface side of the glass core, a cavity inner side surface connected with the cavity opening and extending in a thickness direction of the glass core, and an inner space surrounded by the cavity inner side surface.

At least one side surface of the device portion may be disposed to be spaced apart from the cavity inner side surface facing the one side surface of the device portion.

The encapsulation layer forming step may comprise a placement process of placing the encapsulation layer-forming composition between the cavity inner side surface and one side surface of the device portion, and a curing process of curing the encapsulation layer-forming composition to form the encapsulation layer.

The preliminary substrate may have a gap aspect ratio (Arg) of 30 or less as represented by Equation 1 below.

$$Arg = \frac{e h}{g} \qquad [ Equation 1 ]$$

In Equation 1, the eh is a height of the device portion, and the g is a minimum value of a distance between a first point located on a side surface of the device portion and a second point located on the cavity opening.

The g value may be 20 μm to 500 μm.

A difference value between a coefficient of thermal expansion α1 of the encapsulation layer and a coefficient of thermal expansion of the glass core may be 40 ppm/° C. or less.

A coefficient of thermal expansion α2 of the encapsulation layer may be 140 ppm/° C. or less.

A modulus of elasticity of the encapsulation layer may be 10 GPa to 300 GPa.

A glass transition temperature of the encapsulation layer may be 70° C. to 130° C.

The encapsulation layer-forming composition may comprise an epoxy-based resin and a curing agent.

The encapsulation layer-forming composition may comprise a filler in an amount of 45 wt % or more and 80 wt % or less.

### BRIEF DESCRIPTION OF THE DRAWINGS

FIG. 1 is a cross-sectional view illustrating a preliminary substrate prepared through a preparation step of the present disclosure.

FIG. 2 is a cross-sectional view illustrating a packaging substrate prepared through an encapsulation layer forming step of the present disclosure.

### DETAILED DESCRIPTION

Hereinafter, embodiments will be described in detail with reference to the accompanying drawings so that those skilled in the art to which the present invention pertains may easily carry out the invention. However, the present invention may be embodied in various different forms, and is not limited to the embodiments described herein. Throughout the specification, the same reference numerals are assigned to similar parts.

In the entire specification, the term “combinations thereof” included in Markush-type expressions means a mixture or combination of one or more selected from a group consisting of components described in the Markush-type expressions, and means to include one or more selected from the group consisting of the components.

In the entire specification, terms such as “first,” “second,” or “A,” “B” are used to distinguish the same terms from each other. In addition, unless the context clearly indicates otherwise, singular expressions include plural expressions.

In the present specification, “˜ based” may mean that a compound includes a compound corresponding to “˜” and a derivative of “˜” in the compound.

In the present specification, that B is located on A means that B is located on A directly in contact with A, or B is located on A with another layer interposed therebetween, and is not limited to being interpreted as B being located in contact with a surface of A.

In the present specification, that A is connected with B means that A and B are directly connected, or A and B are connected through another component interposed therebetween, and unless otherwise mentioned, is not limited to being interpreted as A and B being directly connected.

In the present specification, a singular expression is to be interpreted as including singular or plural in meaning, unless there is a special description.

In the present specification, shapes, relative sizes, angles, and the like of respective components in the drawings may be exaggerated for the purpose of explanation and illustration, and the scope of rights is not to be interpreted as limited to the drawings.

In the present specification, that A and B are adjacent means that A and B are disposed in contact with each other, or A and B are disposed close to each other without contact. In the present specification, the expression that A and B are adjacent is not limited to being interpreted as A and B being disposed in contact with each other, unless otherwise mentioned.

In the present specification, unless otherwise described, physical property values of respective components in the packaging substrate are to be interpreted as being measured at room temperature. Room temperature is 20° C. to 25° C.

Hereinafter, the embodiments will be described in detail.

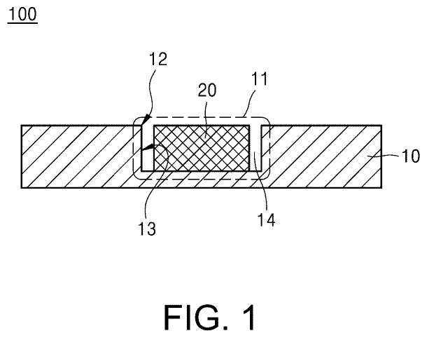

FIG. 1 is a cross-sectional view illustrating a preliminary substrate prepared through a preparation step of the present disclosure. Hereinafter, the embodiment will be described with reference to FIG. 1.

The method of manufacturing a packaging substrate of the present disclosure comprises: a preparation step of preparing a preliminary substrate including a glass core on which a device portion including a device is mounted; and an encapsulation layer forming step of manufacturing the packaging substrate by forming an encapsulation layer surrounding at least a portion of the device portion with an encapsulation layer-forming composition.

### [Preparation Step]

The preliminary substrate (100) may comprise a glass core (10).

The glass core (10) may have a shape of a glass substrate. The glass core (10) may, for example, be applied as alkali borosilicate plate glass, non-alkali borosilicate plate glass, non-alkali alkaline earth borosilicate plate glass, and the like, and may be applied if it is plate glass applied as an electronic component. The glass core (10) may be applied as a glass substrate for an electronic device, and, for example, may be one manufactured by SCHOTT, AGC, Corning, and the like, but is not limited thereto.

The glass core (10) may comprise a through via (not shown) penetrating in a thickness direction of the glass core (10).

The through via comprises an inner space (not shown) and a via inner surface (not shown) surrounding the inner space. The inner space means an empty space, and the via inner surface means a surface of the glass core (10) formed inside the through via.

The through via may have a diameter varying in the thickness direction of the glass core (10). The through via may have a substantially uniform diameter in the thickness direction of the glass core (10).

A surface of the glass core (10) may comprise an upper surface and a side surface connected with the upper surface and formed in a thickness direction of the glass core (10). The surface of the glass core (10) may comprise a lower surface facing the upper surface.

That the side surface is formed in the thickness direction of the glass core (10) is to be interpreted as including not only that the side surface forms a perpendicular with the upper surface of the glass core (10) but also that at least a portion of the side surface forms an angle (inclined angle) different from 90 degrees with the upper surface.

The side surface may be a flat surface, and may be a curved surface.

The glass core (10) may be one on which a device portion (20) is mounted.

The glass core (10) may comprise a cavity portion (11) that is a space formed by being recessed on the upper surface side. The device portion (20) may be disposed in the cavity portion (11). The cavity portion (11) may be a region in which the device portion (20) is mounted.

That the space formed by being recessed on the upper surface side of the glass core (10) means to be interpreted as including both that a portion of the upper surface side of the glass core (10) is recessed in the thickness direction of the glass core (10), and that the glass core (10) is penetrated in the thickness direction and formed.

The cavity portion (11) comprises a cavity opening (10) disposed on the upper surface side of the glass core (10), a cavity inner side surface (13) connected with the cavity opening (10) and extending in the thickness direction of the glass core (10), and an inner space (14) surrounded by the cavity inner side surface (13).

The cavity opening (10) may be disposed in contact with the upper surface of the glass core (10). The cavity opening (10) may constitute an inner edge of the upper surface of the glass core (10).

That the cavity inner side surface (13) is formed to extend in the thickness direction of the glass core (10) is to be interpreted as including not only that the cavity inner side surface (13) forms a perpendicular with the upper surface of the glass core (10) but also that at least a portion of the cavity inner side surface (13) forms an angle (inclined angle) different from 90 degrees with the upper surface.

The cavity inner side surface (13) may be a flat surface, and may be a curved surface.

The preliminary substrate (100) comprises a device portion (20) mounted in the cavity portion (11). The device portion (20) may be electrically connected with the packaging substrate being manufactured.

At least one side surface of the device portion (20) may be disposed to be spaced apart from the cavity inner side surface (13) facing the one side surface of the device portion (20). Each side surface of the device portion (20) may be disposed to be spaced apart from the cavity inner side surface (13) facing the corresponding side surface of the device portion (20).

The device portion (20) may be the device itself, and may be a device package. The device package is one in which one or more devices are packaged by a device insulating material. The device insulating material may surround at least a portion of the surface of the device. The device insulating material may fix one or more devices in the device package and may provide insulation to a desired region in the device package.

The device may include not only semiconductor devices such as CPU, GPU, and memory chips, but also capacitor devices, transistor devices, impedance devices, and other modules. That is, if it is a semiconductor device mounted on a semiconductor device, it may be applied as the device without limitation.

The device insulating material may comprise a material capable of properly fixing the device and preventing electrical short-circuit. The device insulating material may, for example, comprise any one selected from a group consisting of an epoxy-based resin, a polyimide-based resin, a polyurethane-based resin, a polyester-based resin, an acrylate-based resin, a polyamide-based resin, and combinations thereof.

In the preparation step, the preliminary substrate (100) in which the device portion (20) is already mounted in the cavity portion (11) in the glass core (10) may be introduced, and the preliminary substrate (100) may be prepared by mounting the device portion (20) on the glass core (10) having the cavity portion (11) formed therein.

The present disclosure may introduce the preliminary substrate (100) in which the gap aspect ratio Arg represented by Equation 1 below is 30 or less, or may dispose the device portion (20) in the cavity portion (11) so that the Arg value is 30 or less.

$$Arg = \frac{e h}{g} \qquad [ Equation 1 ]$$

In Equation 1, the eh is a height of the device portion (20), and the g is a minimum value of a distance between a first point located on a side surface of the device portion (20) and a second point located on the cavity opening (10).

The present disclosure may control the Arg value of the preliminary substrate (100) to adjust a shape of an empty space formed between the device portion (20) and the cavity inner side surface (13). Through this, the encapsulation layer-forming composition having viscosity at a predetermined level or more may be easily dispensed into the empty space, and formation of voids in the encapsulation layer may be efficiently suppressed.

The Arg value of the preliminary substrate (100) may be 30 or less. The Arg value may be 25 or less. The Arg value may be 20 or less. The Arg value may be 15 or less. The Arg value may be 10 or less. The Arg value may be 7 or less. The Arg value may be 0.1 or more. The Arg value may be 0.5 or more. The Arg value may be 1 or more. In this case, the encapsulation layer-forming composition containing a filler may sufficiently fill the empty space formed in the cavity portion (11).

The g value may be 20 μm to 500 μm. The g value may be 50 μm or more. The g value may be 100 μm or more. The g value may be 400 μm or less. The g value may be 300 μm or less.

The eh value may be 300 μm to 600 μm. The eh value may be 350 μm or more. The eh value may be 400 μm or more. The eh value may be 550 μm or less.

In this case, the encapsulation layer-forming composition may be easily introduced into a space formed between the cavity inner side surface (13) and the device portion (20). In addition, the shape and volume of the formed encapsulation layer are controlled, so that an intensity of stress applied to the glass core (10) due to thermal expansion of the encapsulation layer may be stably controlled.

A thickness of the glass core (10) may be 100 μm or more. The thickness may be 200 μm or more. The thickness may be 300 μm or more. The thickness may be 3000 μm or less. The thickness may be 2000 μm or less. The thickness may be 1000 μm or less. In this case, the glass core (10) may have mechanical properties suitable to be applied to the packaging substrate.

### [Encapsulation Layer Forming Step]

In the encapsulation layer forming step, an encapsulation layer surrounding at least a portion of the device portion (20) is formed with an encapsulation layer-forming composition. In the encapsulation layer forming step, the encapsulation layer-forming composition may be cured to form the encapsulation layer.

The encapsulation layer forming step may comprise a placement process of placing the encapsulation layer-forming composition between the cavity inner side surface and one side surface of the device portion, and a curing process of curing the encapsulation layer-forming composition to form the encapsulation layer.

### [Placement Process]

The encapsulation layer-forming composition may comprise an epoxy-based resin and a curing agent.

The present disclosure may apply an epoxy-based resin to the encapsulation layer-forming composition, thereby imparting controlled elasticity to the encapsulation layer. Through this, while the encapsulation layer stably supports and protects the device portion (20), excessive increase of stress applied to the glass core (10) due to thermal expansion of the encapsulation layer may be suppressed. In addition, the encapsulation layer having such characteristics may exhibit stable bonding strength with an insulating layer formed on the glass core (10).

The epoxy-based resin may comprise two or more epoxy groups. The epoxy-based resin may be any one selected from a group consisting of bisphenol A type epoxy resin, brominated bisphenol A type epoxy resin, bisphenol F type epoxy resin, biphenyl type epoxy resin, novolac type epoxy resin, alicyclic epoxy resin, naphthalene type epoxy resin, silicone epoxy copolymer resin, and combinations thereof.

A weight average molecular weight of the epoxy-based resin may be 1,000 g/mol or less. The weight average molecular weight may be 800 g/mol or less. The weight average molecular weight may be 600 g/mol or less. The weight average molecular weight may be 100 g/mol or more.

The curing agent of the present disclosure is not limited as long as it is a compound capable of functioning as a curing agent for the epoxy-based resin. For example, the curing agent may be an acid anhydride curing agent, an aromatic amine, a phenol resin, an imidazole-based compound, and the like.

The present disclosure may apply 0.3 equivalents or more of the curing agent per 1 equivalent of the epoxy group in the epoxy-based resin. The present disclosure may apply 0.5 equivalents or more of the curing agent per 1 equivalent of the epoxy group in the epoxy-based resin. The present disclosure may apply 0.7 equivalents or more of the curing agent per 1 equivalent of the epoxy group in the epoxy-based resin. The present disclosure may apply 2 equivalents or less of the curing agent per 1 equivalent of the epoxy group in the epoxy-based resin. The present disclosure may apply 1.5 equivalents or less of the curing agent per 1 equivalent of the epoxy group in the epoxy-based resin.

The encapsulation layer-forming composition may further comprise a filler. The filler may help the encapsulation layer to have mechanical properties within a predetermined range in the present disclosure, particularly thermal expansion characteristics and elasticity.

The filler may comprise inorganic particles. The filler may be inorganic particles. For example, the filler may be silica, titania, alumina, and the like.

An average particle diameter of the filler may be 150 nm or less. The average particle diameter may be 120 nm or less. The average particle diameter may be 100 nm or less. The average particle diameter may be 80 nm or less. The average particle diameter may be 10 nm or more. The average particle diameter may be 30 nm or more. In this case, the encapsulation layer may be helped to have desired mechanical properties. In addition, it may be easy to implement a conductive layer having fine pitch on the encapsulation layer.

The encapsulation layer-forming composition may comprise a filler in an amount of 45 wt % or more and 80 wt % or less.

The present disclosure may adjust the filler content in the encapsulation layer-forming composition within a predetermined range in the present disclosure. Through this, while lowering the difference in thermal expansion characteristics between the encapsulation layer and the glass core (10), the encapsulation layer-forming composition may easily fill the empty space in the cavity portion (11).

The encapsulation layer-forming composition may comprise a filler in an amount of 45 wt % or more. The encapsulation layer-forming composition may comprise a filler in an amount of 50 wt % or more. The encapsulation layer-forming composition may comprise a filler in an amount of 75 wt % or less. The encapsulation layer-forming composition may comprise a filler in an amount of 70 wt % or less. In this case, the encapsulation layer may stably fix the device portion (20) in the cavity portion (11) and may form an encapsulation layer that does not apply excessive stress to the glass core (10) during a manufacturing process in a high-temperature atmosphere.

The encapsulation layer-forming composition may comprise a solvent. The solvent is not limited as long as it is one that may be generally applied in the technical field. For example, the solvent may comprise an aliphatic hydrocarbon solvent, an aromatic hydrocarbon solvent, an ether, an ester, and the like.

The encapsulation layer-forming composition may further comprise an additive. The additive is not limited as long as it is one that may be generally applied in the technical field. For example, the additive may comprise a defoaming agent, a coupling agent, a flame retardant, a surfactant, and the like.

In the placement process, the encapsulation layer-forming composition may be melt-mixed and filled into a region where the encapsulation layer is to be formed. The melt-mixed encapsulation layer-forming composition may be placed through an injection device. The melt-mixed encapsulation layer-forming composition may be placed through a heating cylinder.

The present disclosure may control a temperature of the heating cylinder within a predetermined range in the placement process. Through this, the encapsulation layer-forming composition may have a melting viscosity suitable for filling narrow gaps, thereby suppressing formation of voids in the encapsulation layer.

The temperature of the heating cylinder means a temperature measured at a tip of the heating cylinder.

In the placement process, the temperature of the heating cylinder may be 40° C. to 70° C. The temperature may be 45° C. or more. The temperature may be 50° C. or more. The temperature may be 65° C. or less. The temperature may be 60° C. or less. In this case, the encapsulation layer-forming composition may sufficiently fill the empty space in the cavity portion (11).

The present disclosure may apply an encapsulation layer-forming composition having a controlled viscosity at 25° C. The encapsulation layer-forming composition having controlled viscosity characteristics may have flow characteristics suitable for filling an empty space having a complicated shape in the cavity portion (11) in the placement process, and may also help an encapsulation layer formed by curing the composition to have thermal expansion characteristics suitable for application to a glass substrate.

A viscosity of the encapsulation layer-forming composition at 25° C. may be 12,000 cps to 38,000 cps. The viscosity may be 15,000 cps or more. The viscosity may be 18,000 cps or more. The viscosity may be 20,000 cps or more. The viscosity may be 35,000 cps or less. The viscosity may be 32,000 cps or less. The viscosity may be 30,000 cps or less. The viscosity may be 28,000 cps or less. In this case, it may contribute to stably suppressing defects occurring in the encapsulation layer during the manufacturing process.

The viscosity at 25° C. of the encapsulation layer-forming composition is measured with a viscometer after adjusting the temperature of the composition to 25° C.

### [Curing Process]

In the curing process, the encapsulation layer-forming composition placed in the region to be formed into the encapsulation layer may be cured to form the encapsulation layer. The encapsulation layer-forming composition may be cured by heating to form the encapsulation layer.

In the curing process, a heat treatment temperature may be 120° C. or more. The heat treatment temperature may be 130° C. or more. The heat treatment temperature may be 140° C. or more. The heat treatment temperature may be 250° C. or less. The heat treatment temperature may be 230° C. or less. The heat treatment temperature may be 200° C. or less.

In the curing process, a heat treatment time may be 30 minutes or more. The heat treatment time may be 40 minutes or more. The heat treatment time may be 50 minutes or more. The heat treatment time may be 200 minutes or less. The heat treatment time may be 180 minutes or less. The heat treatment time may be 150 minutes or less.

In this case, a curing reaction may stably proceed within the encapsulation layer-forming composition, thereby helping to form an encapsulation layer having excellent physical properties.

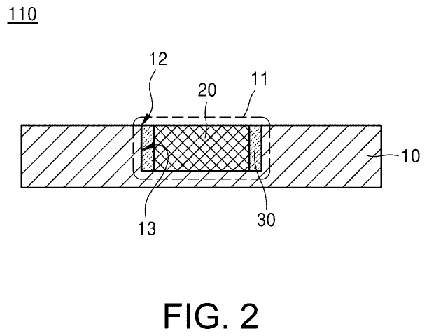

FIG. 2 is a cross-sectional view illustrating the packaging substrate manufactured through the method of manufacturing a packaging substrate of the present disclosure. Hereinafter, the embodiment will be described with reference to FIG. 2.

The packaging substrate (110) comprises a glass core (10) including a cavity portion (11) which is a region where a device is mounted, and an encapsulation layer (30) surrounding at least a portion of the device portion (20). The packaging substrate (110) comprises the device portion (20) including a device. Regarding the glass core (10), the device portion (20), and the cavity portion (11), the description of FIG. 1 above is applied as it is. Hereinafter, the description will focus on the parts that are different.

The encapsulation layer (30) may be formed from the encapsulation layer-forming composition described above.

In the packaging substrate (110) manufactured through the encapsulation layer forming step, the encapsulation layer (30) may be formed to surround at least a portion of the device portion (20). The encapsulation layer (30) may surround at least a portion of one side surface of the device portion (20). The encapsulation layer (30) may surround the entire side surfaces of the device portion (20). The encapsulation layer (30) may surround at least a portion of an upper surface of the device portion (20). The encapsulation layer (30) may surround the upper surface of the device portion (20). The encapsulation layer (30) may surround at least a portion of the upper surface and side surfaces of the device portion (20). The encapsulation layer (30) may surround at least a portion of the overall surface of the device portion (20).

At least a portion of the encapsulation layer (30) may be disposed in contact with a surface of the device portion (20). The encapsulation layer (30) may be disposed in contact with the surface of the device portion (20). The encapsulation layer (30) may be disposed to be spaced apart from the surface of the device portion (20).

The manufactured packaging substrate (110) of the present disclosure may control a difference between thermal expansion characteristics of the encapsulation layer (30) and thermal expansion characteristics of the glass core (10). Through this, even when the substrate is repeatedly exposed to a high-temperature environment during the manufacturing process, such as in an insulating layer forming process, occurrence of defects such as cracks in the glass core (10) may be effectively suppressed.

A difference value between a coefficient of thermal expansion α1 of the encapsulation layer (30) and a coefficient of thermal expansion of the glass core (10) may be 40 ppm/° C. or less. The difference value may be 35 ppm/° C. or less. The difference value may be 30 ppm/° C. or less. The difference value may be 5 ppm/° C. or more. In this case, an intensity of thermal stress occurring in the glass core (10) in a process of forming an insulating layer on the glass core (10) may be reduced to a level below a certain threshold.

The difference value between the coefficient of thermal expansion α1 of the encapsulation layer (30) and the coefficient of thermal expansion of the glass core (10) is an absolute value of a value obtained by subtracting the coefficient of thermal expansion of the glass core (10) from the coefficient of thermal expansion α1 of the encapsulation layer (30).

A coefficient of thermal expansion α2 of the encapsulation layer (30) may be 140 ppm/° C. or less. The α2 value may be 135 ppm/° C. or less. The α2 value may be 130 ppm/° C. or less. The α2 value may be 125 ppm/° C. or less. The α2 value may be 120 ppm/° C. or less. The α2 value may be 115 ppm/° C. or less. The α2 value may be 110 ppm/° C. or less. The α2 value may be 100 ppm/° C. or more.

In this case, when the packaging substrate (110) is exposed to a high-temperature environment during the manufacturing process, damage to the glass core (10) caused by the encapsulation layer (30) may be stably suppressed.

The coefficient of thermal expansion α1 is a coefficient of thermal expansion of a measurement target measured in a temperature range from room temperature to a glass transition temperature of the measurement target. The coefficient of thermal expansion α2 is a coefficient of thermal expansion of a measurement target measured in a temperature range higher than the glass transition temperature of the measurement target.

The coefficient of thermal expansion may be measured using a Thermal Mechanical Analyzer (TMA) through a thermomechanical analysis method. For example, the coefficient of thermal expansion may be measured through a Q400 model TMA of TA INSTRUMENTS.

In the present disclosure, elasticity of the encapsulation layer (30) may be controlled within a predetermined range of the present disclosure. In this case, a force applied to the cavity inner side surface (13) by the encapsulation layer (30) thermally expanding in a high-temperature manufacturing environment may be reduced.

A modulus of elasticity of the encapsulation layer (30) may be 10 GPa to 30 GPa. The modulus of elasticity may be 11 GPa or more. The modulus of elasticity may be 12 GPa or more. The modulus of elasticity may be 25 GPa or less. The modulus of elasticity may be 20 GPa or less. The modulus of elasticity may be 15 GPa or less. In this case, stress applied to the cavity inner side surface (13) at high temperature may be reduced.

A modulus of elasticity value of the encapsulation layer (30) may be measured through Dynamic Mechanical Analysis (DMA).

A glass transition temperature of the encapsulation layer (30) may be 70° C. to 130° C. The glass transition temperature may be 80° C. or more. The glass transition temperature may be 90° C. or more. The glass transition temperature may be 100° C. or more. The glass transition temperature may be 125° C. or less. The glass transition temperature may be 120° C. or less. The glass transition temperature may be 115° C. or less. Through this, the encapsulation layer (30) may have flexibility suitable for application to the glass core (10) while stably fixing the device portion (20).

The glass transition temperature is measured using a Differential Scanning calorimeter (DSC). Specifically, after placing a specimen in the DSC, a first scan is carried out by applying a heating rate of 10° C./min for the first scan. After quenching the specimen, a second scan is carried out under the same conditions as the first scan to measure the glass transition temperature and the like.

For example, a Q2000 model of TA Instruments may be applied to measure the glass transition temperature of a first polyester resin.

[Step after Encapsulation Layer Forming Step]

The method of manufacturing a packaging substrate of the present disclosure may further comprise a redistribution layer forming step after the encapsulation layer forming step.

In the redistribution layer forming step, a redistribution layer may be formed on the glass core (10). In the redistribution layer forming step, a redistribution layer may be formed under the glass core (10).

The redistribution layer forming step may comprise a process of forming a conductive layer and a process of forming an insulating layer.

In the process of forming the conductive layer, the conductive layer may be formed on a surface of the glass core (10) and/or on the insulating layer to be described below. In the case of forming a conductive layer on a mounted device, an insulating layer may first be formed on an upper surface of the device, and then the conductive layer may be formed on the insulating layer.

The conductive layer may be formed by a dry method or a wet method.

The dry method is a method of forming a seed layer by sputtering in a region where the conductive layer is to be placed, and forming the conductive layer by plating in the region where the seed layer is formed. In forming the seed layer, metals such as titanium, chromium, nickel, and the like may be sputtered, and the metals may be sputtered together with copper. Through sputtering, an anchor effect in which a surface on which the conductive layer is placed and deposited metal particles interact with each other may appear, thereby improving adhesion of the conductive layer.

The wet method is a method of performing metal plating after treating a primer on a portion where formation of the conductive layer is required. The primer may comprise a compound having a functional group such as an amine. Depending on the degree of adhesion intended, the primer may comprise a compound having a functional group such as an amine together with a silane coupling agent. When applying a silane coupling agent, after pre-treating a surface to be treated with a silane coupling agent, a primer layer may be formed by coating the pre-treated region with a compound having an amine group.

After forming the seed layer or primer layer, a metal may be plated to form the conductive layer. In forming the conductive layer, copper plating may be applied, but is not limited thereto. Before metal plating, a portion in the seed layer or primer layer where formation of the conductive layer is not required may be inactivated, or a portion where formation of the conductive layer is required may be activated, and then plating may be performed. A method of activation or inactivation treatment may comprise light irradiation treatment in which a laser of a specific wavelength is irradiated, chemical treatment, and the like. However, without applying activation or inactivation treatment, after performing metal plating, the conductive layer may be patterned by etching in a predetermined shape.

In the redistribution layer forming step, an insulating layer may be formed so as to surround at least a portion of the conductive layer. The insulating layer may be formed so as to surround at least a portion of an upper surface of the conductive layer. The insulating layer may be formed so as to surround at least a portion of a side surface of the conductive layer.

The insulating layer and the conductive layer may be disposed in a mixed state on the glass core (10). The conductive layer having a pattern shape may be formed in a form embedded in the insulating layer.

The insulating layer may be applied as long as it is one that may be applied as an insulating layer to a semiconductor device or a packaging substrate. The insulating layer may, for example, be applied as an epoxy-based resin containing a filler. The insulating layer may, for example, be formed through a build-up layer material such as Ajinomoto Build-up Film (ABF) of Ajinomoto, or an undercoat material, but is not limited thereto.

The insulating layer may be formed by laminating an uncured or semi-cured insulating film and then curing it.

In the redistribution layer forming step, by completing formation of a redistribution layer having a predetermined structure on an upper side and/or a lower side of the glass core (10), the packaging substrate (110) may be prepared.

### [Other Steps]

As needed, an upper terminal and the like may additionally be formed on an upper portion and/or a side of the packaging substrate (110), and bumps may additionally be formed on a lower portion of the packaging substrate (110). The bumps may be disposed in a predetermined shape under the redistribution layer disposed under the glass core (10). For example, the bumps may be disposed on a lower surface of the packaging substrate (110) so as to contact a main board and the like.

Hereinafter, the embodiments will be described in more detail through specific examples. The following examples are merely examples to assist in understanding the present disclosure, and the scope of the present disclosure is not limited thereto.

### Preparation Example: Formation of Packaging Substrate

Example 1: A glass substrate having a thickness of 510 μm and a full cavity formed with a width of 40 mm to 60 mm and a length of 40 mm to 60 mm was prepared. A device having a height of 480 μm was disposed in the cavity. A distance between the cavity inner side surface and the device was applied as 150 μm, and a polyimide tape was attached to a lower surface of the glass substrate to fix the position of the device.

Subsequently, an empty space formed between the device and the cavity inner side surface was filled with U8410-302SNS8AG, an encapsulation layer-forming composition of Namics, through injection equipment. During filling, a temperature of a cylinder tip was applied as 40° C. to 60° C.

After completion of filling, the substrate was heat-treated at 150° C. to 160° C. for 1 hour to 2 hours to form an encapsulation layer.

After formation of the encapsulation layer, an insulating layer was formed by laminating and curing ABF GL103, a build-up film having a thickness of 20 μm, on the glass substrate to prepare the packaging substrate.

Example 2: A packaging substrate was prepared under the same conditions as in Example 1, except that U8410-207R6 of Namics was applied as the encapsulation layer-forming composition.

Example 3: A packaging substrate was prepared under the same conditions as in Example 1, except that U8410-302 of Namics was applied as the encapsulation layer-forming composition.

Example 4: A packaging substrate was prepared under the same conditions as in Example 1, except that U8410-207R6 of Namics was applied as the encapsulation layer-forming composition.

Comparative Example 1: A packaging substrate was prepared under the same conditions as in Example 1, except that 8803LF (Rev.3) of Poly Tech was applied as the encapsulation layer-forming composition.

Comparative Example 2: A packaging substrate was prepared under the same conditions as in Example 1, except that U8437-2 of Namics was applied as the encapsulation layer-forming composition.

Comparative Example 3: A packaging substrate was prepared under the same conditions as in Example 1, except that U8410-406 of Namics was applied as the encapsulation layer-forming composition.

Comparative Example 4: A packaging substrate was prepared under the same conditions as in Example 1, except that 8507FS of Poly Tech was applied as the encapsulation layer-forming composition.

Processing conditions for each Example and Comparative Example are described in Table 1 below.

### Evaluation Example: Evaluation of Physical Properties of Encapsulation Layer

Values of coefficients of thermal expansion of the encapsulation layer and the glass substrate were measured for each Example and Comparative Example. The coefficient of thermal expansion was measured with a TMA (Thermal Mechanical Analyzer) of Q400 model of TA INSTRUMENTS using a thermomechanical analysis method.

Thereafter, after separating a portion of the encapsulation layer from the packaging substrates of each Example and Comparative Example, a modulus of elasticity of the separated encapsulation layer was measured. The modulus of elasticity was measured through Dynamic Mechanical Analysis (DMA).

The glass transition temperature of the separated encapsulation layer was measured using a Differential Scanning calorimeter (DSC) Q2000 of TA Instruments.

The measurement values for each Example and Comparative Example are described in Table 2 below.

### Evaluation Example: Evaluation of Crack Occurrence in Glass Substrate

After forming the encapsulation layer by placing and curing the encapsulation layer-forming composition in the glass substrate in the packaging substrate manufacturing process of each Example and Comparative Example, the glass substrate was observed with an optical microscope.

After forming the encapsulation layer, an insulating layer was formed by laminating and curing a build-up film on the glass substrate, and the glass substrate was observed with an optical microscope.

After forming the insulating layer, the packaging substrate was left to complete final curing for 20 minutes at 120° C., and then the glass substrate was observed with an optical microscope.

At this time, when a defect having a length of 100 μm or more was present in the glass substrate, it was determined as a crack. When a crack did not occur, it was judged as P, and when a crack occurred, it was judged as F.

The evaluation results for each Example and Comparative Example are described in Table 3 below.

### Evaluation Example: Moisture Resistance Evaluation

Each packaging substrate of the Examples and Comparative Examples was left in an atmosphere of 125° C. for 24 hours, and then left in an atmosphere of 30° C., 60% RH for 96 hours. Thereafter, whether delamination of the encapsulation layer and the insulating layer occurred was observed with an optical microscope. When delamination of neither the encapsulation layer nor the insulating layer occurred, it was evaluated as P, and when delamination occurred in at least one of the encapsulation layers or the insulating layer, it was evaluated as F.

The evaluation results for each Example and Comparative Example are described in Table 3 below.

### Evaluation Example: Heat Resistance Evaluation

The temperature of an atmosphere in which each packaging substrate of the Examples and Comparative Examples was placed was lowered to −40° C., and then the atmospheric temperature was raised to 165° C. over 1 hour, and the atmospheric temperature was maintained at 165° C. for 2 hours. Thereafter, the atmospheric temperature was lowered to −40° C. over 1 hour. This process was performed as one thermal cycle, and a total of 100 thermal cycles were performed, and whether cracks occurred in the glass substrate and whether delamination of the encapsulation layer occurred were observed with an optical microscope.

Thereafter, an additional total of 400 thermal cycles were performed, and whether cracks occurred in the glass substrate and whether delamination of the encapsulation layer occurred were observed with an optical microscope.

When it was observed with an optical microscope that cracks did not occur in the glass substrate and delamination of the encapsulation layer and the insulating layer did not occur, it was evaluated as P, and when cracks occurred in the glass substrate or delamination occurred in at least one of the encapsulation layer or the insulating layer, it was evaluated as F. The evaluation results for each Example and Comparative Example are described in Table 3 below.

### Evaluation Example: HTSL (High Temperature Storage Life) Evaluation

Each packaging substrate of the Examples and Comparative Examples was heated at 150° C. for 500 hours, and then whether cracks occurred in the glass substrate and whether delamination of the encapsulation layer and the insulating layer occurred were evaluated.

When cracks did not occur in the glass substrate and delamination of the encapsulation layer and the insulating layer did not occur, it was evaluated as P, and when cracks occurred in the glass substrate or delamination occurred in at least one of the encapsulation layers or the insulating layer, it was evaluated as F. 5

The evaluation results for each Example and Comparative Example are described in Table 3 below.

TABLE 1

| | | | Filler |
|---|---|---|---|
| | Encapsulation | Viscosity | content in |
| | layer-forming | at 25° C. | composition |
| | composition | (cps) | (wt %) |
| Example 1 | U8410-302SNS8AG | 25,000 | 53 |
| Example 2 | U8410-207R6 | 20,000 | 60 |
| Example 3 | U8410-302LF1 | 20,000 | 60 |
| Example 4 | U8410-207R6 | 20,000 | 60 |
| Comparative | 8803LF(Rev.3) | 6,700 | 40 |
| Example 1 | | | |
| Comparative | U8437-2 | 40,000 | 65 |
| Example 2 | | | |
| Comparative | U8410-406 | 40,000 | 70 |
| Example 3 | | | |
| Comparative | 8507FS | 10,500 | 50 |
| Example 4 | | | |

TABLE 2

| | | | Glass | |
|---|---|---|---|---|
| | | | transition | Modulus of |
| | CTE α1 | CTE α2 | temperature | elasticity |
| | (ppm/° C.) | (ppm/° C.) | (° C.) | (GPa) |
| Example 1 | 29 | 126 | 113 | 12 |
| Example 2 | 29 | 109 | 92 | 13 |
| Example 3 | 29 | 102 | 108 | 12 |
| Example 4 | 29 | 109 | 92 | 13 |
| Comparative | 26 | 154 | 164 | 9 |
| Example 1 | | | | |
| Comparative | 32 | 100 | 137 | 7 |
| Example 2 | | | | |
| Comparative | 19 | 70 | 178 | 6.8 |
| Example 3 | | | | |
| Comparative | 40 | 150 | 10 | 3 |
| Example 4 | | | | |

TABLE 3

| | Crack | Crack | | | | | |
|---|---|---|---|---|---|---|---|
| | occurrence | occurrence | Crack | | | | |
| | evaluation | evaluation | occurrence | | | | |
| | (after | (after | evaluation | | Heat | Heat | |
| | encapsulation | insulating | (after | Moisture | resistance | resistance | |
| | layer | layer | final | resistance | evaluation | evaluation | HTSL |
| | formation) | formation) | curing) | evaluation | (100 cycles) | (500 cycles) | evaluation |
| Example 1 | P | P | P | P | P | P | P |
| Example 2 | P | P | P | P | P | P | P |
| Example 3 | P | P | P | P | P | P | P |
| Example 4 | P | P | P | P | P | P | P |
| Comparative | P | P | P | F | F | F | F |
| Example 1 | | | | | | | |
| Comparative | F | F | F | F | P | P | F |
| Example 2 | | | | | | | |
| Comparative | P | P | P | F | F | F | F |
| Example 3 | | | | | | | |
| Comparative | P | F | F | F | F | F | F |
| Example 4 | | | | | | | |

In Table 3 above, Examples 1 to 4 were all evaluated as P in the crack occurrence evaluation, the moisture resistance evaluation, the heat resistance evaluation, and the HTSL evaluation, whereas in the case of Comparative Example 1, it was evaluated as F in the moisture resistance evaluation, the heat resistance evaluation, and the HTSL evaluation. These evaluation results support that, when the encapsulation layer-forming composition having controlled viscosity and the like of the present disclosure is applied to the method of manufacturing a packaging substrate, and a position of the device portion in the cavity portion is adjusted as intended in the present disclosure, the moisture resistance, heat resistance, and delamination resistance of the encapsulation layer may be improved, and stress applied to the glass substrate may be reduced.

Thus, the preferred embodiments of the present invention have been described in detail, but the scope of the present invention is not limited thereto, and various modifications and improvements made by those skilled in the art using the basic concept of the present invention defined in the following claims also belong to the scope of the present invention.

What is claimed is:

1. A method of manufacturing a packaging substrate, comprising:
a preparation step of preparing a preliminary substrate including a glass core on which a device portion including a device is mounted; and
an encapsulation layer forming step of manufacturing the packaging substrate by forming an encapsulation layer surrounding at least a portion of the device portion with an encapsulation layer-forming composition;
wherein the glass core comprises a cavity portion that is a space formed by being recessed on an upper surface side of the glass core;
wherein the device portion is disposed in the cavity portion; and
wherein a viscosity of the encapsulation layer-forming composition at 25° C. is 12,000 cps to 38,000 cps.

2. The method of claim 1, wherein the cavity portion comprises a cavity opening disposed on the upper surface side of the glass core, a cavity inner side surface connected with the cavity opening and extending in a thickness direction of the glass core, and an inner space surrounded by the cavity inner side surface,
wherein at least one side surface of the device portion is disposed to be spaced apart from the cavity inner side surface facing the one side surface of the device surface, and
wherein the encapsulation layer forming step comprises a placement process of placing the encapsulation layer-forming composition between the cavity inner side surface and one side surface of the device portion, and a curing process of curing the encapsulation layer-forming composition to form the encapsulation layer.

3. The method of claim 1, wherein the cavity portion comprises a cavity opening disposed on the upper surface side of the glass core, a cavity inner side surface connected with the cavity opening and extending in a thickness direction of the glass core, and an inner space surrounded by the cavity inner side surface,
wherein at least one side surface of the device portion is disposed to be spaced apart from the cavity inner side surface facing the one side surface, and
wherein the preliminary substrate has a gap aspect ratio (Arg) of 30 or less as represented by Equation 1 below:
$$Arg = \frac{e h}{g} \qquad [ Equation 1 ]$$
wherein, in Equation 1, eh is a height of the device portion, and g is a minimum value of a distance between a first point located on a side surface of the device portion and a second point located on the cavity inner side surface.

4. The method of claim 3, wherein the g value is 20 μm to 500 μm.

5. The method of claim 1, wherein a difference value between a coefficient of thermal expansion α1 of the encapsulation layer and a coefficient of thermal expansion of the glass core is 40 ppm/° C. or less.

6. The method of claim 1, wherein a coefficient of thermal expansion α2 of the encapsulation layer is 140 ppm/° C. or less.

7. The method of claim 1, wherein a modulus of elasticity of the encapsulation layer is 10 GPa to 30 GPa.

8. The method of claim 1, wherein a glass transition temperature of the encapsulation layer is 70° C. to 130° C.

9. The method of claim 1, wherein the encapsulation layer-forming composition comprises an epoxy-based resin and a curing agent.

10. The method of claim 1, wherein the encapsulation layer-forming composition comprises a filler in an amount of 45 wt % or more and 80 wt % or less.
